(19) United States
(12) Patent Application Publication
(10) Pub. No.: US 2008/0272947 A1
(43) Pub. Date: Nov. 6, 2008

(54) System Clock Generator Circuit

(75) Inventor: Haruhisa Yamaguchi, Kyoto (JP)

Correspondence Address: CANTOR COLBURN, LLP, 20 Church Street, 22nd Floor, Hartford, CT, 06103, US

(73) Assignee: ROHM CO., LTD, Ukyo-ku (JP)

(21) Appl. No.: 11/597,177

(22) PCT Filed: May 26, 2004
(86) PCT No.: PCT/JP04/07197

§ 371 Date: Nov. 21, 2006

(51) Int. Cl. H03M 1/66; H04M 1/00

(52) U.S. Cl. 341/144; 455/550.1

(57) ABSTRACT

A system clock generator circuit for use in a D/A converter that allows the clock of any frequency to be inputted and also allows usage limiting-conditions to be simplified. A system clock generator circuit for use in a D/A converter for demodulating one-bit digital input data, which has been obtained by ΔΣ modulation scheme, into analog output data in synchronism with an internal system clock and for outputting the analog output data, comprises a counter circuit for receiving external system clocks and LR clocks (LRCLK) having predetermined repetitive frequencies to count the number of the external system clocks included in one period of the LR clocks; a timing generator circuit for generating mask signals for thinning, in accordance with the count value as counted by the counter circuit, the external system clocks at predetermined thinning timings; and a mask circuit for masking the external system clocks by use of the mask signals and thinning the clocks in the masked portions to generate internal system clocks.

### 1. FIELD OF THE INVENTION

The present invention relates to a system clock generating circuit for generating an internal system clock of a DA converter. In particular, the invention relates to a system clock generating circuit for use in a DA converter which demodulates analog output data from 1-bit digital input data obtained by a ΔΣ modulation method.

### 2. DESCRIPTION OF THE RELATED ART

Among known conventional DA converters using a ΔΣ modulation method is an apparatus described in Japanese Patent Laid-Open Publication No. Hei 9-186600 (hereinafter, referred to as patent document 1).

Besides, one described in Japanese Patent Laid-Open Publication No. Hei 9-148885 (hereinafter, referred to as patent document 2) has been known as an apparatus for converting a sampling frequency rate, which is used in converting 1-bit digital data obtained by the ΔΣ modulation method into multi-bit digital data having a different sampling frequency.

For stereo audio DA converters, ones described in the product brochure from Burr-Brown Corporation, PCM1737 and PCM1739 “stereo audio D/A converters” (hereinafter, referred to as non-patent document 1) have been known.

In recent years, cellular phones, or mobile communication terminals, are becoming remarkably widespread. For the sake of processing of audio signals, cellular phones contain DA converters and AD converters for audio processing. The DA converters for audio processing adopt an oversampling technology and a ΔΣ modulation technology, and have the facilities of rendering the operation sampling rates of the ΔΣ modulation units variable.

As a result, it is possible to achieve high-performance multifunction DA converters by changing the sampling rates depending on the applications of external analog low-pass filters (LPF). The DA converters are thus used widely not only in cellular phones but also in DVD-M, DVD-A, and such applications as home theater systems and AV amplifiers.

FIG. 5 is a diagram showing the configuration of a DA converter which uses the oversampling technology and the ΔΣ conversion technology. Similar circuits also appear in the non-patent document 1.

The DA converter comprises an input interface circuit 51, an 8× oversampling digital filter 52, a DA conversion circuit 53 using the ΔΣ modulation method, an output circuit 54, and a system clock generating circuit 55. The output circuit 54 is made of a low-pass filter and an output amplifier. The system clock generating circuit 55 generates a predetermined internal system clock in response to an external system clock, and supplies it to the individual circuits 51, 52, and 53.

The input interface circuit 51 receives an LR clock LRCK for making a selection between an L channel and an R channel, a bi-clock BCK, and 1-bit digital input data DATA obtained by the ΔΣ modulation method.

For the circuit configuration of the DA conversion circuit 53 using the ΔΣ modulation method, one shown in FIG. 1 of the patent document 1 has been known.

FIG. 6 is a block diagram schematically showing the configuration of an AD conversion circuit for obtaining 1-bit digital input data from an analog input signal by using the ΔΣ modulation method. The AD conversion circuit comprises a prefilter circuit 61, an accumulator circuit 62, an integrator 63, a comparator 64, a delay circuit 65, and a 1-bit DA conversion circuit 66. Since the details of operation of the circuit shown in FIG. 6 are well known, detailed description thereof will be omitted.

FIG. 7 is a waveform chart showing the relationship among various signals appearing on the circuit of FIG. 6.

An audio analog signal of the L or R channel selected by the LR clock LRCK (A) is quantized in 16 to 24 bits as shown in (B). The signal is also oversampled by a not-shown 8× oversampling signal processing circuit, so that a quantized analog signal such as shown in (C) is input to the prefilter 61. Then, the circuit of FIG. 6 applies signal processing through ΔΣ modulation, and outputs 1-bit digital input data having such a waveform as shown in (D).

This digital output is input to the input interface circuit 51 as the data DATA shown in FIG. 5, so that the original analog signal is reproduced and output from the output circuit 54 as the L channel output or R channel output.

Now, suppose that the 1-bit digital input data shown in FIG. 7(D) is demodulated into an analog signal by using the oversampling technology and the ΔΣ conversion technology described above and by using a DA converter such as shown in FIG. 5. In this case, the timing cycle of the internal system clock to be supplied to the DA conversion circuit 53 must be changed as needed.

The DA converter having such a circuit configuration as shown in FIG. 5 is typically provided with an external system clock, or a reference frequency (fₛ), of 10 to 200 kHz in the sampling rate. The external system clock is multiplied by predetermined factors (128, 192, 256, 384, 512, 768, . . . ) inside the system clock generating circuit 55, and these multiplied internal system clocks are automatically selected and supplied according to need.

Techniques for changing the sampling rate of the sampling frequency as above have been also disclosed in the patent document 2, whereas any of the techniques are effected by multiplying the external system clock by predetermined regular factors.

Thus, all the techniques have had the problem that it is impossible to generate internal system clocks having arbitrary sampling rates in accordance with input data.

### SUMMARY OF THE INVENTION

The present invention has been achieved in order to solve the foregoing problem. It is thus an object of the present invention to provide a system clock generating circuit for use in a DA converter which can demodulate 1-bit digital input data obtained by a ΔΣ modulation method into analog data in synchronization with an internal system clock having an arbitrary sampling rate.

A system clock generating circuit according to the present invention is one for use in a DA converter which demodulates 1-bit digital input data obtained by a ΔΣ modulation method into analog output data and outputs the same in synchronization with an internal system clock. The system clock generating circuit comprises: a counter circuit which receives an external system clock having a predetermined repetition frequency and an LR clock (LRCLK), and counts the number of clocks of the external system clock included in a single cycle of the LR clock; a timing generating circuit which generates a mask signal for dropping the external system clock at predetermined drop timing in accordance with the count value counted by the counter circuit; and a mask circuit which masks the external system clock with the mask signal, thereby dropping the clock of the masked part to generate an internal system clock.

The present invention also provides the system clock generating circuit in which the drop timing is changed depending on the repetition frequency of the external system clock and/or the external system clock divided in frequency is used as the external system clock.

The present invention also provides the system clock generating circuit in which one single cycle of the LR clock is divided evenly, the count value is distributed and allocated among the individual divided areas, and the mask signal is generated in accordance with the allocations.

The present invention also provides the system clock generating circuit in which the repetition frequency of the external system clock is selected arbitrarily from the range of 256 and 1024 times a reference sampling rate (fₛ).

The present invention also provides the system clock generating circuit in which the drop timing is set in accordance with the number of clocks to be dropped, such that it is at every sixteen clocks when 0 to 15 clocks are to be dropped, at every eight clocks with 16 to 31 clocks to be dropped, at every four clocks with 32 to 63 clocks to be dropped, at every two clocks with 64 to 127 clocks to be dropped, and at every single clock with 128 to 255 clocks to be dropped.

The present invention also provides a DA converter incorporating the system clock generating circuit, and a cellular phone incorporating this DA converter.

### BRIEF DESCRIPTION OF THE DRAWINGS

FIG. 1 is a block diagram showing the configuration of a system clock generating circuit according to an embodiment of the present invention;

FIG. 2 is a timing chart showing various signals used in FIG. 1;

FIG. 3 is an enlarged timing chart of FIG. 2;

FIG. 4 is a circuit diagram showing the detailed configuration of the timing generating circuit shown in FIG. 1;

FIG. 5 is a block diagram showing the configuration of a DA converter using a ΔΣ modulation method;

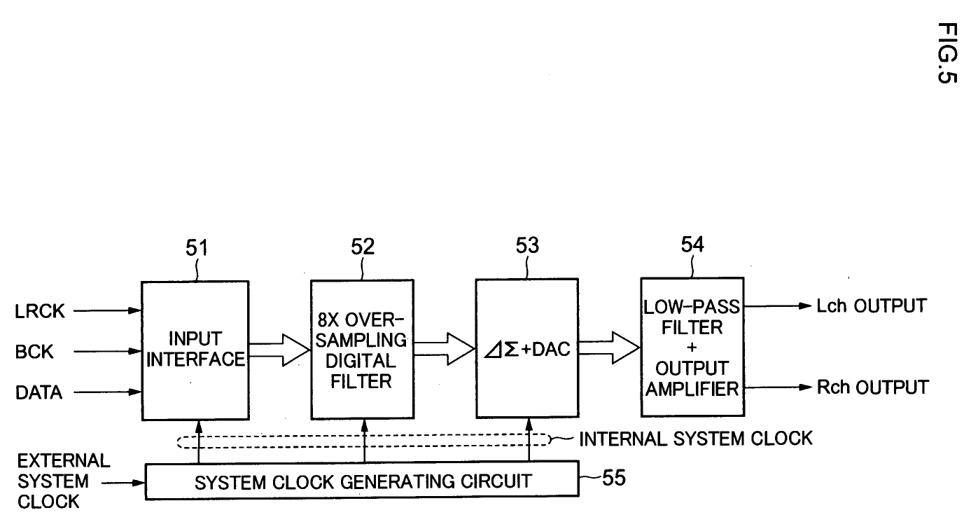

FIG. 6 is a block diagram showing the circuit configuration of an AD converter using the ΔΣ modulation method; | and

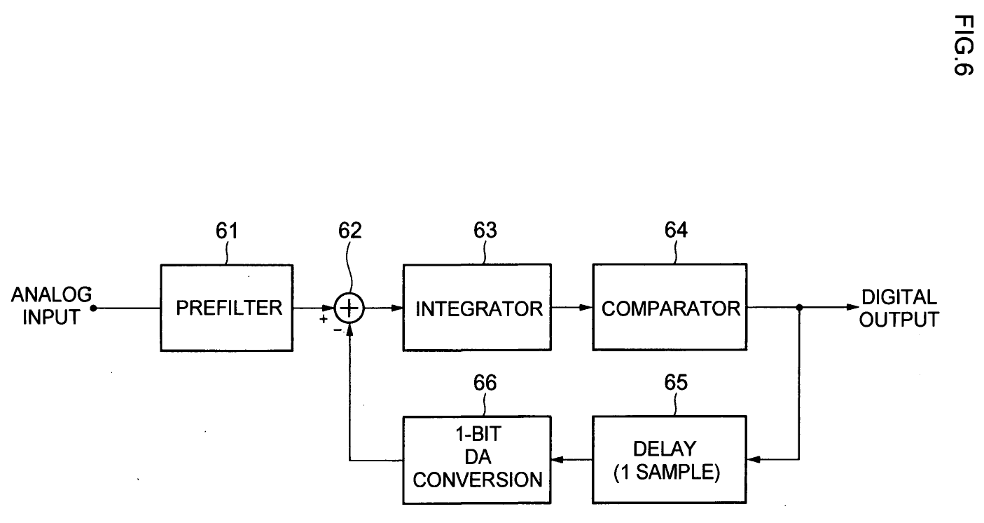

FIG. 7 is a timing chart showing various waveforms used in FIG. 6.

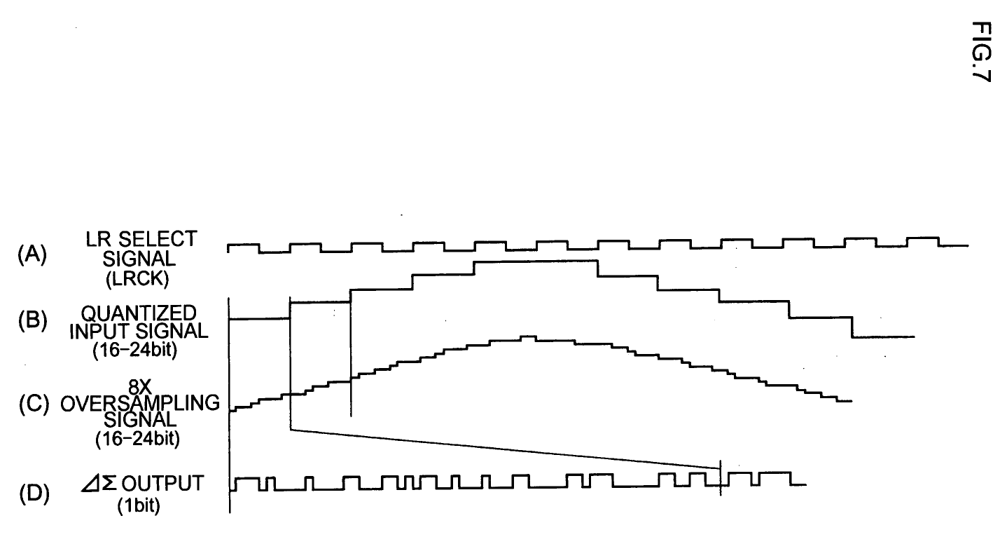

### DETAILED DESCRIPTION OF THE INVENTION

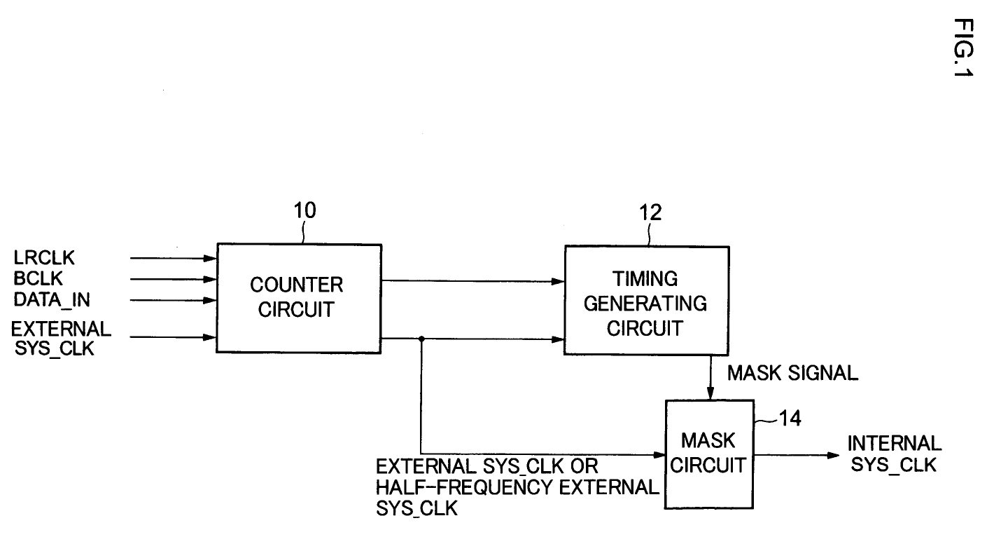

FIG. 1 is a block diagram showing the configuration of a system clock generating circuit according to an embodiment of the present invention.

The system clock generating circuit comprises a counter circuit 10, a timing generating circuit 12, and a mask circuit 14. An LR clock LRCLK, a bi-clock BCLK, 1-bit digital input data DATA-IN, and an external system clock SYS_CLK are input to the counter circuit 10. A predetermined internal system clock SYS_CLK is obtained as the output of the mask circuit 14.

The counter circuit 10 counts the number of clocks of the external system clock included in a single cycle of the LR clock.

In accordance with the count value counted by the counter circuit 10, the timing generating circuit 12 generates a mask signal for dropping the external system clock at predetermined timing, and supplies the same to the mask circuit 14.

The mask circuit 14 receives the mask signal from the timing generating circuit 12, and either the external system clock or the external system clock divided by half in frequency (hereinafter, referred to as half-frequency external system clock) from the counter circuit 10.

The external system clock or the half-frequency external system clock supplied from the counter circuit 10 is masked with the mask signal. Consequently, the clocks of the masked parts are dropped, and the resultant is output from the mask circuit 14 as the internal system clock. This output internal system clock is used to drive a DA conversion circuit.

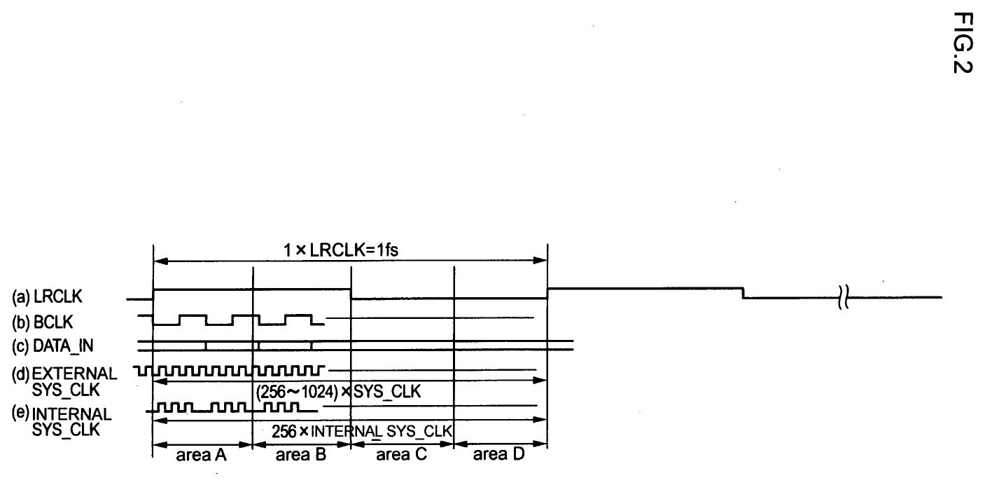

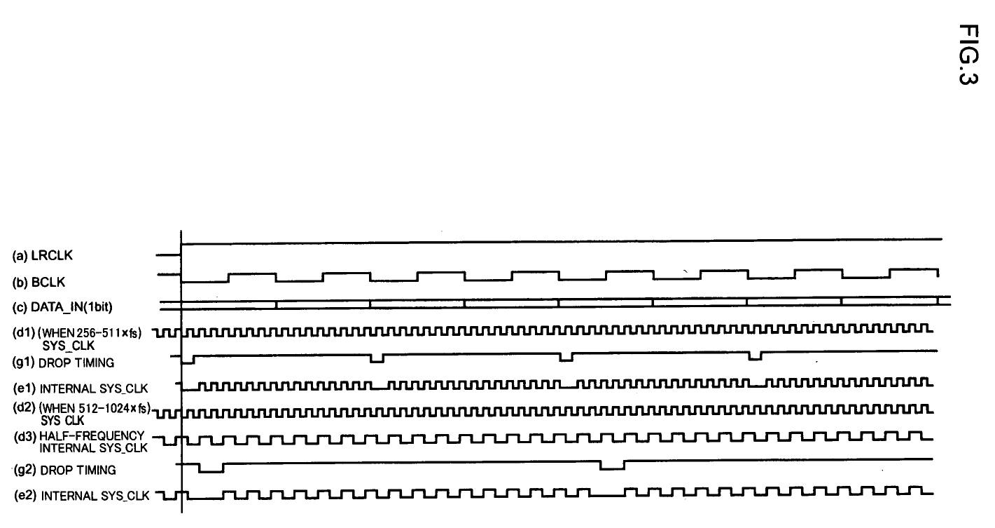

FIGS. 2 and 3 are timing charts for explaining the circuit operation of FIG. 1. Incidentally, FIG. 3 is an enlarged chart showing the operation for a single cycle of the LR clock in FIG. 2.

As shown in FIG. 2, the external system clock is generated with a sampling rate 256 to 1024 times a reference sampling rate (fₛ). This makes it possible to generate the internal system clock having an arbitrary frequency within the frequency range of this external system clock, or 256 to 1024 times the reference sampling rate. For that purpose, the external system clock is dropped at predetermined drop timing in accordance with the count value counted by the counter circuit 10 of FIG. 1, whereby such an internal system clock as shown in FIG. 2(e) is generated.

To suppress a reduction in distortion factor, the drop timing must be distributed evenly within a single cycle of the LR clock. In the example shown in FIG. 2, the one single cycle is thus divided into four areas A, B, C, and D. The clocks to be dropped are distributed evenly among these areas.

Next, description will be given of the circuit operation of the system clock generating circuit shown in FIG. 1.

The counter circuit 10 counts the number of rises (the number of clocks) of the external system clock in a single cycle (1 fₛ) of the LR clock. Then, the result is passed to the timing generating circuit 12.

When the count falls within the range of 256 and 511 fₛ, the external system clock is supplied as is to the timing generating circuit 12. When the count falls within the range of 512 and 1023 fₛ, the half-frequency external system clock is supplied to the timing generating circuit 12.

The timing generating circuit 12 generates the timing to drop the external system clock based on the count of this external system clock in a single cycle (1 fₛ) of the LR clock. Since the drop timing must be distributed within the one single cycle as evenly as possible, the number of clocks to be dropped is divided into four and allocated evenly to the areas A, B, C, and D as shown in FIG. 2.

Depending on the required number of drops, the basic timing of dropping is generated as follows:

The number of drops

0 to 15 clocks generated at every sixteen clocks

16 to 31 clocks generated at every eight clocks

32 to 63 clocks generated at every four clocks

64 to 127 clocks generated at every two clocks

128 to 255 clocks generated at every single clock

As employed here, the clock refers to the one supplied from the counter circuit 10. When the count falls within the range of 256 to 511 fₛ, the clock is the external system clock. With 512 to 1023 fₛ, it is the half-frequency external system clock.

In accordance with the drop timing generated by the timing generating circuit 12, the mask circuit 14 masks the clock (the external system clock or the half-frequency external system clock) supplied from the counter circuit 10 for dropping. The signal generated by this mask circuit 14 is used as the internal system clock for ΔΣ processing.

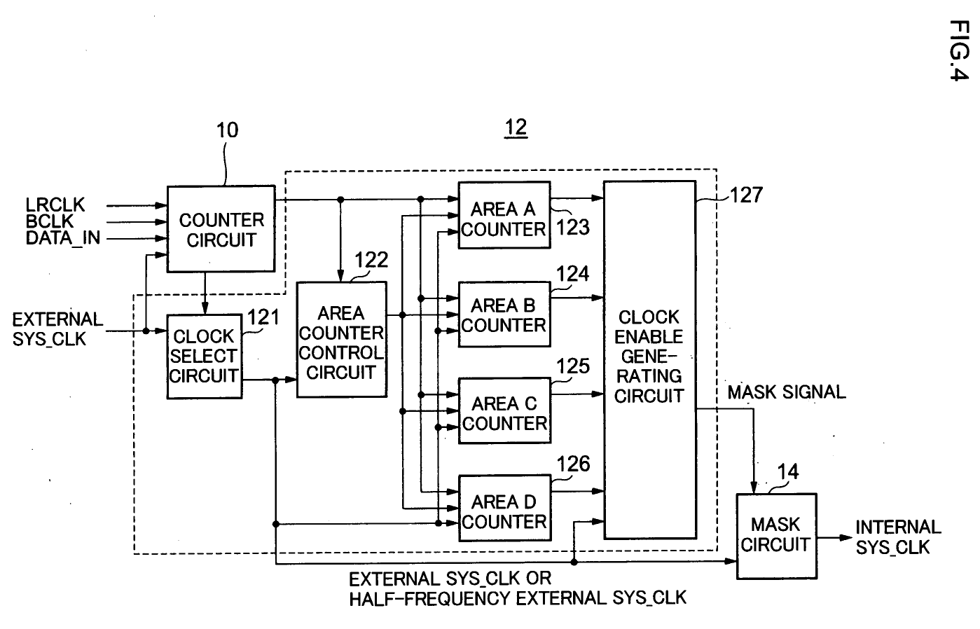

FIG. 4 is a circuit diagram showing the detailed configuration of the timing generating circuit 12 in the system clock generating circuit shown in FIG. 1.

The timing generating circuit 12 comprises a clock select circuit 121, an area counter control circuit 122, an area A counter 123, an area B counter 124, an area C counter 125, an area D counter 126, and a clock enable generating circuit 127.

The clock select circuit 121 is used to select either one of the outputs of the external system clock and the half-frequency external system clock in accordance with the result of count of the external system clock in a single cycle of the LR clock.

The area counter control circuit 122 controls the start and end of count of the individual area counters 123 to 126.

The area A counter 123, the area B counter 124, the area C counter 125, and the area D counter 126 are reference counters for generating clock enable signals in the areas A, B, C, and D, respectively.

The clock enable generating circuit 127 generates an enable signal for dropping clocks with reference to the clock enable signals from the area counters 123 to 126. The enable signal is output to the mask circuit 14 as the mask signal.

In the mask circuit 14, the mask signal generated by the clock enable generating circuit 127 and the signal selected by the clock select circuit 121 are multiplied by each other to generate the internal system clock.

As described above, according to the present invention, the frequency of the internal system clock can be selected arbitrarily from the range of 256 and 1024 times the reference sampling rate (fₛ).

This makes it possible to select the internal system clock for DA conversion freely in accordance with the digital input data, thereby allowing a significant relaxation of restrictions for use.

Moreover, the timing to drop the external system clock can be allocated evenly within a single cycle of the LR clock, thereby suppressing a reduction in the distortion factor.

The present invention can be used widely as a timing clock generating circuit for DA converters. It can also be used widely for cellular phones, DVD-M, and DVD-A incorporating those DA converters, as well as for home theater systems, AV amplifiers, etc.

1. A system clock generating circuit for use in a DA converter which demodulates 1-bit digital input data obtained by a ΔΣ modulation method into analog output data and outputs the same in synchronization with an internal system clock, the system clock generating circuit comprising:
a counter circuit which receives an external system clock having a predetermined repetition frequency and an LR clock (LRCLK), and counts a number of clocks of the external system clock included in a single cycle of the LR clock;
a timing generating circuit which generates a mask signal for dropping the external system clock at predetermined drop timing in accordance with a count value counted by the counter circuit; and
a mask circuit which masks the external system clock with the mask signal, thereby dropping the clock of a masked part to generate an internal system clock.

2. The system clock generating circuit according to claim 1, wherein
the drop timing is changed depending on the repetition frequency of the external system clock and/or the external system clock divided in frequency is used as the external system clock.

3. The system clock generating circuit according to claim 1, wherein
one single cycle of the LR clock is divided evenly, the count value is distributed and allocated among individual divided areas, and the mask signal is generated in accordance with the allocations.

4. The system clock generating circuit according to claim 1, wherein
the repetition frequency of the external system clock is selected arbitrarily from a range of 256 and 1024 times a reference sampling rate (fₛ).

5. The system clock generating circuit according to claim 1, wherein
the drop timing is set in accordance with the number of clocks to be dropped, such that it is at every sixteen clocks when 0 to 15 clocks are to be dropped, at every eight clocks with 16 to 31 clocks to be dropped, at every four clocks with 32 to 63 clocks to be dropped, at every two clocks with 64 to 127 clocks to be dropped, and at every single clock with 128 to 255 clocks to be dropped.

6. (canceled)

7. (canceled)

8. A DA converter incorporating the system clock generating circuit according to claim 1.

9. A DA converter incorporating the system clock generating circuit according to claim 5.

10. A cellular phone incorporating the DA converter according to claim 8.
